(19) United States
(12) Patent Application Publication
(10) Pub. No.: US 2008/0128784 A1
(43) Pub. Date: Jun. 5, 2008

(54) FLASH MEMORY DEVICE

(76) Inventor: Jin-Hyo Jung, Gyeongi-do (KR)

Correspondence Address: SHERR & NOURSE, PLLC, 620 HERNDON PARKWAY, SUITE 200, HERNDON, VA, 20170, US

(21) Appl. No.: 11/936,375

(22) Filed: Nov. 7, 2007

(30) Foreign Application Priority Data
Nov. 30, 2006 (KR) 10-2006-0119469

(51) Int. Cl. H01L 21/3205; H01L 29/78

(52) U.S. Cl. 257/319; 438/588; 257/E29.264; 257/E21.159

(57) ABSTRACT

A flash memory device having a region doped with a first impurity formed on a semiconductor substrate, a first polysilicon pattern having a substantially rectangular configuration formed on and/or over the region; a second polysilicon pattern having a substantially rectangular configuration formed on and/or over the first polysilicon pattern; a plurality of charge trapping layers formed on and/or over sidewalls of the first and second polysilicon patterns; and a plurality of control gates formed on and/or over the charge trapping layers.

The present application claims priority under 35 U.S.C. 119 and 35 U.S.C. 365 to Korean Patent Application No. 10-2006-0119469 (filed on Nov. 30, 2006), which is hereby incorporated by reference in its entirety.

### BACKGROUND

A flash memory device has the advantages of an erasable programmable read-only memory (EPROM) having programming and erasing characteristics and of an electrically erasable programmable read-only memory (EEPROM) having electrically programming and erasing characteristics.

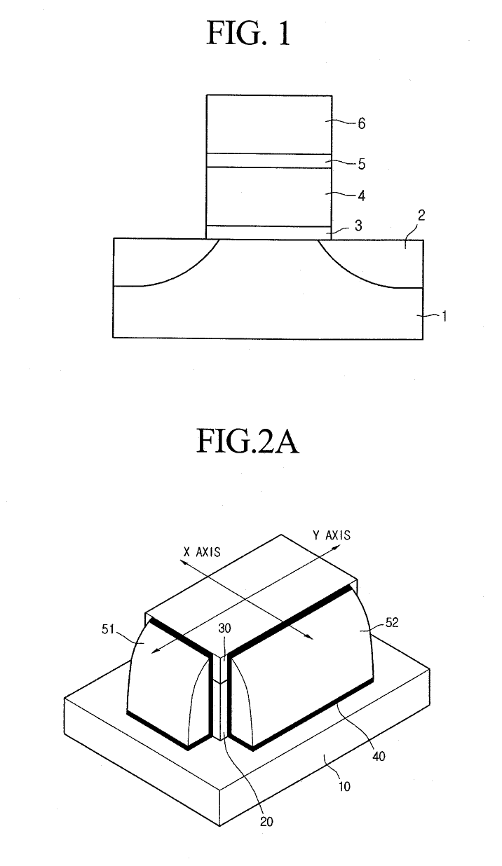

As illustrated in example FIG. 1, a flash memory device may include tunnel oxide layer 3, floating gate 4, insulating layer 5, and control gate 6 sequentially formed on and/or over silicon substrate 1. Source/drain regions 2 may be formed on both sides of silicon substrate 1 to complete the formation of a transistor. Such a flash memory device may include a plurality of transistors arranged in a matrix pattern, thereby constituting a plurality of cells. Each transistor can store 1 bit of data in performing both electrical programming and erasing operations.

Such flash memory devices, however, have disadvantages such as lack of high-density and integration due to the source and drain regions being horizontally formed. Moreover, the lack of memory storage of the flash memory device, i.e., the inability to store over 1-bit data.

### SUMMARY

Embodiments relate to a flash memory device having high density and high integration memory characteristics, that can store and erase data of a plurality of bits in and from a single cell.

Embodiments relate to a flash memory device having a region doped with a first impurity formed on a semiconductor substrate, a first polysilicon pattern having a substantially rectangular configuration formed on and/or over the region, a second polysilicon pattern having a substantially rectangular configuration formed on and/or over the first polysilicon pattern; a plurality of charge trapping layers formed on and/or over sidewalls of the first and second polysilicon patterns; and a plurality of control gates formed on and/or over the charge trapping layers. The first polysilicon pattern can be doped with a second impurity different from the first impurity formed over the region and the second polysilicon pattern can be doped with a third impurity identical to the first impurity.

### DRAWINGS

Example FIG. 1 illustrates a flash memory device.

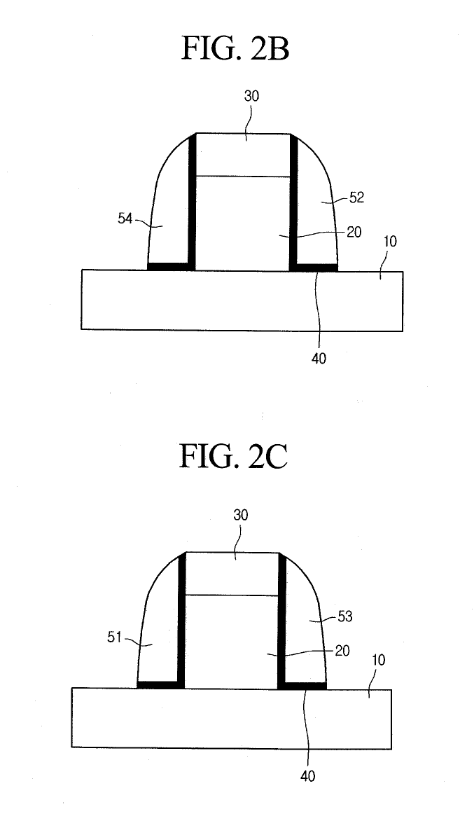

Example FIGS. 2A to 2C illustrates a flash memory device, in accordance with embodiments.

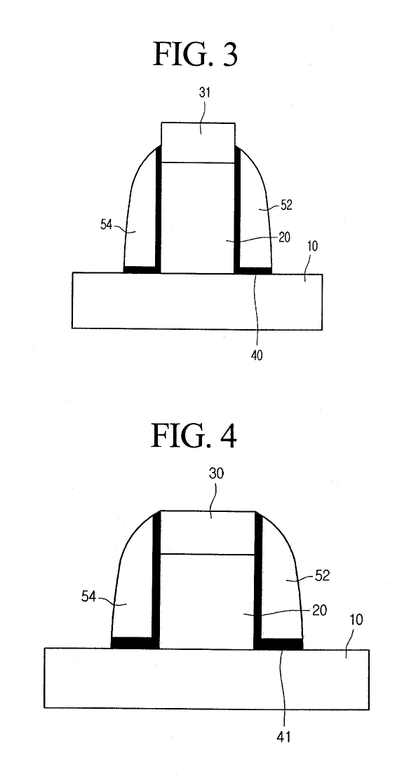

Example FIGS. 3 to 8 illustrate a flash memory device, in accordance with embodiments.

### DESCRIPTION

Further, in the description of the embodiment, it will be understood that, when a layer (or film), a region, a pattern, or a structure is referred to as being “on (above/over/upper)” or “under (below/down/lower)” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

As illustrated in example FIGS. 2A to 2C, region 10 into which a first impurity is doped, can be formed on and/or over a semiconductor substrate. The semiconductor substrate may be an N-type substrate. The first impurity can be an N-type impurity such as phosphorus (P) or arsenic (As). Alternatively, the first impurity can be a P-type impurity such as boron (B).

First polysilicon pattern 20 having a substantially rectangular shape can be formed on and/or over first impurity region 10. First polysilicon pattern 20 can be doped with a second impurity, the second impurity having a different polarity from the first impurity. Accordingly, when the first impurity is an N-type impurity, the second impurity is a P-type impurity. Thus, first polysilicon pattern 20 may form a P-well.

Second polysilicon pattern 30 having a substantially rectangular shape can be formed on and/or over first polysilicon pattern 20. Second polysilicon pattern 30 can be doped with the first impurity. Accordingly, first region 10 doped with the first impurity, first polysilicon pattern 20, and second polysilicon pattern 30 may have a vertical structure in which N-type, P-type, and N-type layers are sequentially deposited having a substantially rectangular shape.

First polysilicon pattern 20 and second polysilicon pattern 30 may each have charge trapping layer 40 on each sidewall thereof. Each charge trapping layer 40 can be typically formed as an insulating layer. Each charge trapping layer 40 may be formed as a multilayer structure. Such multilayer structure may be composed of an ONO layer in which a first oxide layer, a nitride layer, and a second oxide layer are sequentially deposited on and/or over the substrate. Each charge trapping layer 40 can include at least one selected from the group consisting of SiO₂—Si₃N₄—SiO₂, SiO₂—Si₃N₄—Al₂O₃, SiO₂—Si₃N₄—SiO₂, and Si₃N₄—SiO₂.

A plurality of control gates 51, 52, 53 and 54 composed of polysilicon can be formed on and/or over charge trapping layers 40.

As illustrated in example FIG. 3, the flash memory device in accordance with embodiments may include second polysilicon pattern 31 having an uppermost surface that is at least spatially higher than charge trapping layers 40 and control gates 51, 52, 53 and 54. Meaning, the uppermost surface of second polysilicon pattern 31 that extends higher than the upper most surface of charge trapping layers 40 and control gates 51, 52, 53 and 54.

As illustrated in example FIG. 4, the flash memory device in accordance with embodiments may include charge trapping layers 40 interposed between the first polysilicon pattern 20 and second polysilicon pattern 30 and the first, second, third and fourth control gates 51, 52, 53 and 54. Insulating layer 41 different from the respective charge trapping layers 40 can be formed between region 10 doped with the first impurity and control gates 51, 52, 53 and 54. Each charge trapping layer 40 can include an ONO layer in which is sequentially deposited a first oxide layer, a nitride layer, and a second oxide layer. Charge trapping layer 40 having such an ONO structure may be composed of least one selected from the group consisting of SiO₂—Si₃N₄—SiO₂, SiO₂—Si₃N₄—Al₂O₃, SiO₂—Si₃N₄—SiO₂, and Si₃N₄—SiO₂.

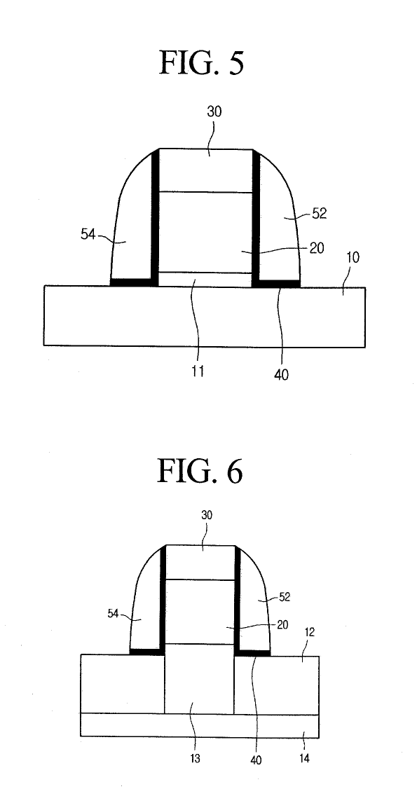

As illustrated in example FIG. 5, a flash memory device in accordance with embodiments may include protrusion 11 interposed between region 10 doped with the first impurity and first polysilicon pattern 20. Protrusion 11 may be formed having a substantially rectangular shape. Protrusion 11 can be composed of the same material as region 10 doped with the first impurity.

As illustrated in example FIG. 6, a flash memory device in accordance with embodiments may include insulating layer pattern 12 having a trench formed on and/or over semiconductor substrate 14. Region 13 doped with the first impurity can be formed in the trench. The uppermost surface of region 13 can be at least higher spatially than the uppermost surface of insulating layer pattern 12.

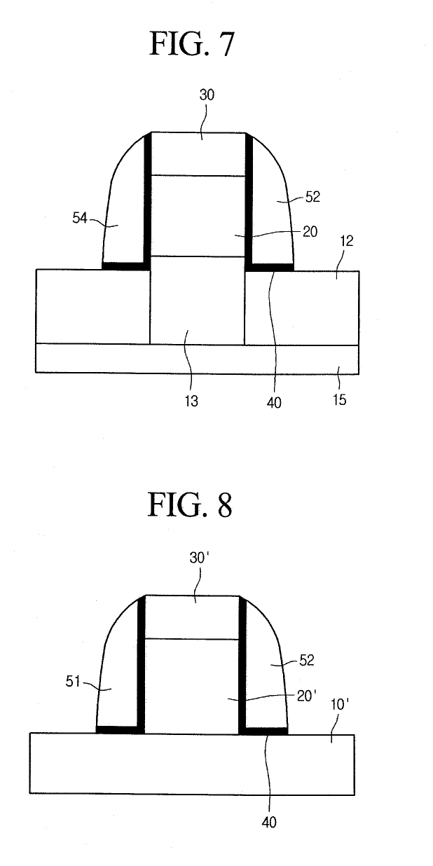

As illustrated in example FIG. 7, a flash memory device in accordance with embodiments may include insulating layer 12 having a trench formed on and/or over semiconductor substrate 15. Region 13 doped with the first impurity can be formed in the trench. The region 13 doped with the first impurity can be composed of N-type polysilicon.

As illustrated in example FIG. 8, a flash memory device in accordance with embodiments may include region 10′ which is doped with a first impurity. The first impurity may be P-type polysilicon. First polysilicon pattern 20′ can be doped with an N-type impurity, thus forming an N-well. Second polysilicon pattern 30′ can be doped with an P-type impurity.

Embodiments relate to a flash memory device including region 10 doped with a first impurity and second polysilicon pattern 30, 31 doped with the first impurity, form source/drain regions having a substantially vertical structure and a substantially rectangular configuration. Thus, the source/drain regions in accordance with embodiments does not have a horizontal structure. Moreover, first polysilicon pattern 20 in which a P-type impurity can be doped to form a P-well may serve as a channel, a travel path, of electric charges (or holes) between region 10 and second polysilicon pattern 30, 31.

Each charge trapping layer 40 formed as an ONO layer may be structured so that the electric charges may be programmed or erased at the nitride layer, the first oxide layer serves as a tunneling oxide layer for tunneling electric charges from the channel to the nitride layer, and the second oxide layer serves as a blocking oxide layer preventing the electric charges from traveling from the nitride layer to the control gates 51, 52, 53 and 54.

When a voltage is applied to first control gate 51, the electric charges (or holes) can be emitted from region 10 serving as the source, and the emitted electric charges are programmed at the nitride layer of charge trapping layer 40. When the voltage is removed from first control gate 51, the electric charges (or holes) programmed at the nitride layer are erased.

Similarly, when a voltage is applied to second control gate 52, the electric charges (or holes) can be emitted from region 10 serving as the source, and thus, can be programmed at the nitride layer of charge trapping layer 40. When the voltage is removed from second control gate 52, the electrons (or holes) programmed at the nitride layer are erased. This process is identically performed through third and fourth control gates 53, 54. Meaning, third and fourth control gates 53, 54 can be operated the same as first and second control gates 51, 52.

Accordingly, in the flash memory device manufactured in accordance with embodiments, charge trapping layers 40 can be located at four places around the channel formed between the source and drain regions of the vertical structure, so that 4-bit data can be stored and erased. Further, when a multi-level bit technique is combined hereto, the stored and erased data can be expanded up to the range from 8 bits to 16 bits using a single cell. Thus, because 4-bit data can be stored and erased by a single cell, the flash memory device can have high-density and high integration characteristics.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate;
a region doped with a first impurity formed over the semiconductor substrate;
a first polysilicon pattern doped with a second impurity different from the first impurity formed over the region;
a second polysilicon pattern doped with a third impurity identical to the first impurity formed over the first polysilicon pattern;
a plurality of charge trapping layers formed on sidewalls of the first polysilicon pattern and the second polysilicon pattern; and
a plurality of control gates formed over the plurality of charge trapping layers,
wherein the first polysilicon pattern and the second polysilicon pattern each have substantially rectangular configurations.

2. The apparatus of claim 1, wherein the first impurity and the third impurity comprise N-type impurities.

3. The apparatus of claim 1, wherein the first impurity and the third impurity comprise P-type impurities.

4. The apparatus of claim 1, wherein the second impurity comprises an N-type impurity.

5. The apparatus of claim 1, wherein the second impurity comprises a P-type impurity.

6. The apparatus of claim 1, wherein each one of the plurality of charge trapping layers comprises an ONO structure.

7. The apparatus of claim 6, wherein the ONO structure comprises a first oxide layer, a nitride layer, and a second oxide layer.

8. The apparatus of claim 6, wherein the ONO structure includes at least one selected from the group consisting of SiO₂—Si₃N₄—SiO₂, SiO₂—Si₃N₄—Al₂O₃, SiO₂—Si₃N₄—SiO₂, and Si₃N₄—SiO₂.

9. The apparatus of claim 1, wherein the uppermost surface of the second polysilicon pattern is at least higher than the uppermost surface of each one of the plurality of control gates.

10. The apparatus of claim 1, wherein each one of the plurality of charge trapping layers is formed between the region and each one of the plurality of control gates and also between the first polysilicon layer, the second polysilicon pattern and each one of the plurality of control gates.

11. The apparatus of claim 1, further comprising an insulating layer formed between the region and each one of the plurality of control gates.

12. The apparatus of claim 1, further comprising a protrusion formed over the region.

13. The apparatus of claim 12, wherein the protrusion is composed of the same material as the region.

14. The apparatus of claim 1, further comprising an insulating layer pattern formed over the semiconductor substrate.

15. The apparatus of claim 14, wherein the insulating layer pattern includes a trench.

16. The apparatus of claim 15, wherein the region is formed in the trench

17. The apparatus of claim 16, wherein the uppermost surface of the region is at least higher than the uppermost surface of the insulating layer pattern.

18. The apparatus of claim 17, wherein the semiconductor substrate comprises a P-type material and the region comprises an N-type polysilicon.

19. A method comprising:
forming a region doped with a first impurity over a semiconductor substrate;
forming a first polysilicon pattern doped with a second impurity different from the first impurity over the region;
forming a second polysilicon pattern doped with a third impurity identical to the first impurity over the first polysilicon pattern;
forming a plurality of charge trapping layers on sidewalls of the first polysilicon pattern and the second polysilicon pattern; and then
forming a plurality of control gates over the plurality of charge trapping layers,
wherein the first polysilicon pattern and the second polysilicon pattern each have substantially rectangular configurations.

20. A method comprising:
forming a region doped with a first impurity over a semiconductor substrate;
forming a first polysilicon pattern doped with a second impurity different from the first impurity over the region;
forming a second polysilicon pattern doped with a third impurity identical to the first impurity over the first polysilicon pattern;
forming a plurality of charge trapping layers on sidewalls of the first polysilicon pattern and the second polysilicon pattern;
forming a plurality of control gates over the plurality of charge trapping layers; and then
forming an insulating layer pattern over the semiconductor substrate;
wherein the first polysilicon pattern and the second polysilicon pattern each have substantially rectangular configurations.
